(19) United States
(12) Patent Application Publication
(10) Pub. No.: US 2012/0028471 A1
(43) Pub. Date: Feb. 2, 2012

(54) METHOD OF MANUFACTURING A SEMICONDUCTOR DEVICE

(75) Inventors: Kenichi Oyama, Yamanashi (JP); Kazuo Yabe, Yamanashi (JP); Hidetami Yaegashi, Yamanashi (JP)

(73) Assignee: TOKYO ELECTRON LIMITED, Tokyo (JP)

(21) Appl. No.: 13/259,764

(22) PCT Filed: Feb. 18, 2011
(86) PCT No.: PCT/JP2011/000901

§ 371 Date: Sep. 23, 2011

(30) Foreign Application Priority Data
Feb. 19, 2010 (JP) 2010-035294

(51) Int. Cl. H01L 21/308

(52) U.S. Cl. 438/694; 257/E21.231; 257/E21.259

(57) ABSTRACT

A method of manufacturing a semiconductor device includes: forming a thin film on a substrate; forming a resist mask which forms a photoresist mask having an elliptical hole pattern on the thin film; shrinking a hole size of the second pattern by forming an insulating film on a side wall of the second pattern of the photoresist layer; and etching the thin film using the insulating film and the photoresist layer which form the second pattern having the shrinked hole size as a mask.

### CROSS-REFERENCE TO RELATED APPLICATIONS

This application is a 35 U.S.C §371 national stage filing of International Application No. PCT/JP2011/000901, filed Feb. 18, 2011, the entire contents of which are incorporated by reference herein, which claims priority to Japanese Patent Application No. 2010-035294, filed Feb. 19, 2010, the entire contents of which are incorporated by reference herein.

### TECHNICAL FIELD

The present disclosure relates to a method of manufacturing a semiconductor device.

### BACKGROUND ART

Photolithographic techniques using photoresist have been employed to form fine circuit patterns in a semiconductor device manufacturing process. In addition, a side wall transfer (SWT) process and other double patterning (DP) process have been considered to create fine circuit patterns.

As one example of such techniques by photolithography, a first formed pattern of a photoresist is transferred onto a hard mask. The hard mask and a resist mask are then used.

In addition, a technique has also been used which forms an opening of a photoresist pattern, heats the photoresist pattern to a glass transition point or higher, shrinks a size of the opening, and performs an etching operation using the shrieked photoresist pattern as a mask

### SUMMARY OF THE INVENTION

It is desirable when using these techniques to create fine circuit patterns by photolithography to form a desired fine pattern more efficiently and improve productivity of semiconductor devices.

In the light of such circumstances, the present disclosure provides some embodiments of a method of manufacturing a semiconductor device, which is capable of forming a desired fine pattern with higher precision and more efficiency than other techniques.

According to one embodiment of the present disclosure, there is provided a method of manufacturing a semiconductor device, the method comprising: forming a thin film on a substrate; forming a photoresist layer having an elliptical hole pattern on the thin film; shrinking a hole size of the elliptical hole pattern by forming an insulating film on a side wall of the elliptical hole pattern; and etching the thin film using the insulating film and the photoresist layer which form the elliptical hole pattern having the shrinked hole size as a mask.

According to another embodiment of the present disclosure, there is provided a method of manufacturing a semiconductor device, the method comprising: etching a thin film formed on a substrate based on a first pattern; depositing the first pattern formed on the thin film; forming a photoresist layer with a second pattern on the first pattern; shrinking a hole size of the second pattern by forming an insulating film on side wall of the second pattern of the photoresist layer; and etching the thin film using the insulating film and the photoresist layer which form the second pattern having the shrinked hole size as a mask.

### BRIEF DESCRIPTION OF THE DRAWINGS

The accompanying drawings, which are incorporated in and constitute a part of the specification, illustrate embodiments of the invention, and together with the general description given above and the detailed description of the embodiments give below, serve to explain the principles of the invention.

FIGS. 1A to 1I are explanatory views for an example method of manufacturing a semiconductor device according to one embodiment of the present disclosure.

FIG. 2 is a flow diagram of the example method of manufacturing a semiconductor device shown in FIGS. 1A to 1I.

FIG. 3 is an electron micrograph showing a shape of polysilicon film according to an embodiment.

FIG. 4 is an electron micrograph showing a shape of second photoresist pattern according to an embodiment.

FIG. 5 is an electron micrograph showing a shape of second photoresist pattern with a shrinked size of hole according to an embodiment.

FIG. 6 is an electron micrograph showing a shape of polysilicon film according to an embodiment.

FIG. 7 is a flow diagram of a method of manufacturing a semiconductor device according to a comparative example.

FIG. 8 is a flow diagram of a method of manufacturing a semiconductor device according to another comparative example.

FIG. 9 is a schematic view of a shape of polysilicon film in a comparative example.

FIG. 10 is an electron micrograph showing a difference between an embodiment and a chemical shrink.

FIG. 11 is a graph showing a relationship between an extent of shrink and a hole size.

FIG. 12 is an electron micrograph showing a shape of polysilicon film according to another embodiment.

FIG. 13 is an electron micrograph showing a shape of polysilicon film according to another embodiment.

FIGS. 14A to 14D are views used to explain a process of another embodiment.

### DETAILED DESCRIPTION

Embodiments of the present disclosure will now be described in detail with reference to the drawings.

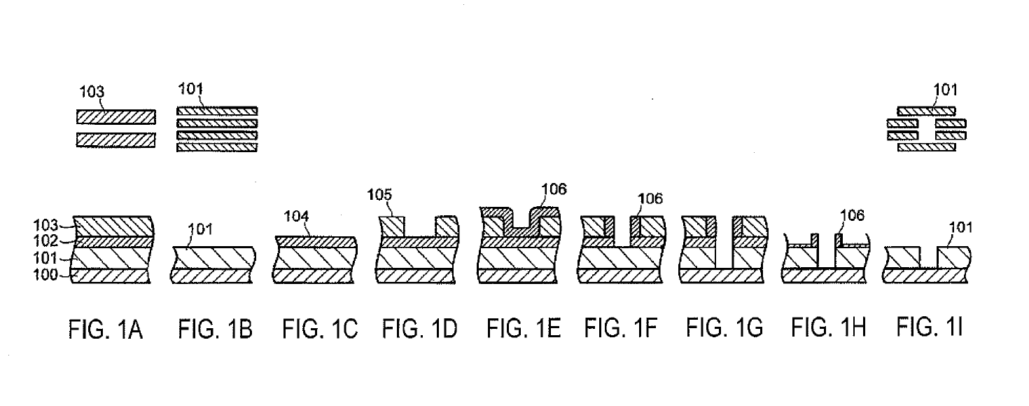

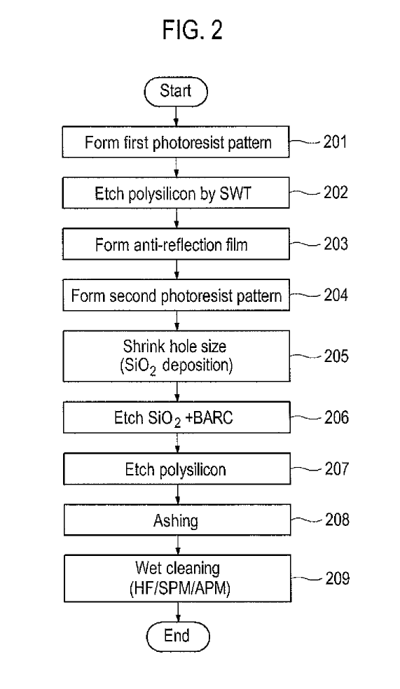

FIGS. 1A to 1I are a partially-enlarged schematic view of a semiconductor wafer as a semiconductor substrate according to one embodiment of the present disclosure, showing processes in a method of manufacturing a semiconductor device according to the embodiment. FIG. 2 is a flow diagram of the method of manufacturing a semiconductor device according to an embodiment.

As shown in FIG. 1A, a polysilicon film 101 as a film to be etched is formed on a semiconductor wafer 100. After forming an anti-reflection film 102 on the polysilicon film 101, a photoresist layer is formed, exposed and developed on the ant-reflection film 102 to form a first photoresist pattern 103 having a line and space shape (Operation 201 in FIG. 2). In addition, a shape of the first photoresist pattern 103 is schematically shown in the upper portion of FIG. 1A when viewed from above. A pitch of the first photoresist pattern 103 is, for example, 80 nm to 100 nm (with a line width of 40 nm to 50 nm), and such a first photoresist pattern 103 may be formed by, for example, ArF liquid immersion lithography or the like.

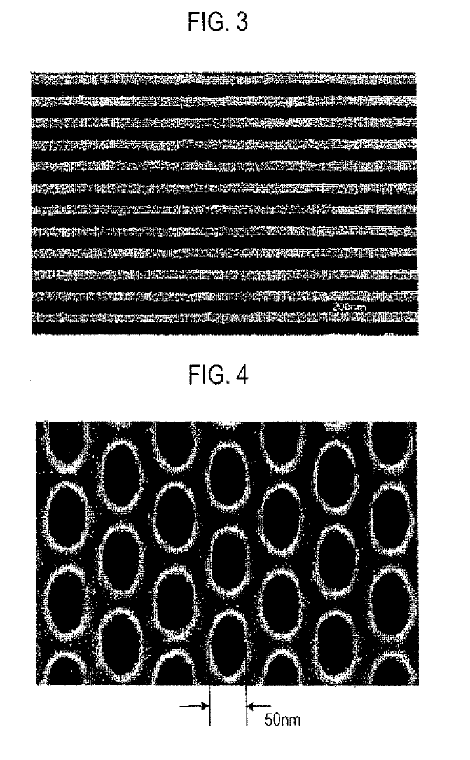

Next, as shown in FIG. 1B, based on the first photoresist pattern 103, a mask of a line and space pattern having a line width of half (about 20 nm) of the first photoresist pattern 103 is formed using a side wall transfer process and the polysilicon film 101 is etched into a line and space shape (Operation 202 in FIG. 2). In addition, a shape of the polysilicon film 101 is schematically shown in the upper portion of FIG. 1B when viewed from above. FIG. 3 is an electron micrograph showing a shape of a polysilicon film 101 actually prepared.

In the side wall transfer, the first photoresist pattern 103 is first slimmed, a silicon dioxide film or the like is formed on a side thereof, and then the first photoresist pattern 103 is removed to form a mask of a line and space pattern having a line width and a pitch which are about half or below of the slimmed first photoresist pattern 103. In addition, this process may employ other double patterning techniques such as LLE (Litho-Litho-Etch), LELE (Litho-Etch-Litho-Etch) and the like, which are well known in the art, instead of the side wall transfer.

Next, as shown in FIG. 1C, an anti-reflection film 104 is formed on the polysilicon film 101 etched into the line and space shape (Operation 203 in FIG. 2).

Next, as shown in FIG. 1D, a photoresist layer is formed, exposed and developed on the anti-reflection film 104 to form a hole-shaped second photoresist pattern 105 (Operation 204 in FIG. 2). A hole size of the second photoresist pattern 105 is, for example, about 50 nm, and such a second photoresist pattern 105 may be formed by, for example, ArF liquid immersion lithography or the like. FIG. 4 is an electron micrograph showing a shape of the second photoresist pattern 105 actually prepared. As seen from the electron micrograph, the hole shape is elliptical in shape in this embodiment.

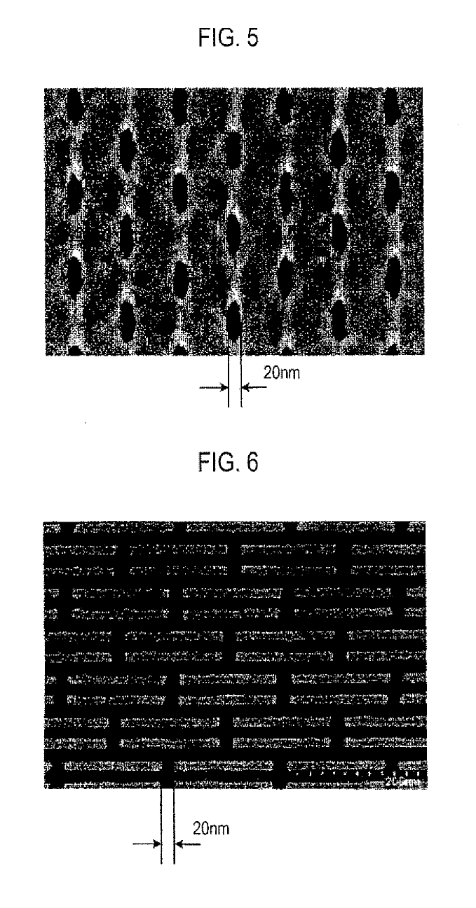

Next, as shown in FIG. 1E, a silicon dioxide (SiO₂) film (insulating film) 106 is formed in the hole of the second photoresist pattern 105 and a shrinking process is then performed to shrink the hole size (Operation 205 in FIG. 2). In this process, it is preferable to used a molecular layer deposition (MLD) method which can form the silicon dioxide film 106 at a low temperature (140° C. or below). In addition, an insulating film to shrink the hole size is not limited to silicon dioxide but may be a film which can be formed at a glass transition point or below of a resist which does not damage the photoresist when the insulating film is formed, such as, for example, aluminum oxide (Al₂O₃), aluminum nitride (AlN), titanium oxide (TiO₂), amorphous silicon, or other metal oxides (HfO₂, ZrO₂ and the like), silicon nitride (SiN)(possibly formed by single wafer plasma), SiON and so on. FIG. 5 is an electron micrograph showing a shape of the second photoresist pattern 105 with the shrinked hole size actually prepared. As seen from this electron micrograph, the size of the hole is shrinked to substantially 20 nm.

Next, as shown in FIG. 1F, a portion of the silicon dioxide film 106 which is on the top of the second photoresist pattern 105 and the bottom of the hole and a portion of the anti-reflection film 104 in the bottom of the hole are etched away using anisotropic etching such as RIE, while leaving a portion of the silicon dioxide film 106 which lies in the inner side wall of the hole (Operation 206 in FIG. 2).

Next, as shown in FIG. 1G, the polysilicon layer 101 is etched using the second photoresist pattern 105 and the portion of the silicon dioxide film 106 lying in the side wall of the hole as a mask (Operation 207 in FIG. 2).

Next, as shown in FIG. 1H, the second photoresist pattern 105 and the anti-reflection layer 104 are etched away or ashed (Operation 208 in FIG. 2).

The etching operation of the silicon dioxide film 106 and the anti-reflection film 104, the etching operation of the polysilicon layer 101 and the etching (ashing) operation of the second photoresist pattern 105 and the anti-reflection film 104 may be performed in series using, for example, a CCP etching apparatus which produces plasma by applying high frequency power between an upper electrode and a lower electrode, based on the following recipes:

(Etching of the Silicon Dioxide Film and the Anti-Reflection Film)

Process gas: CF₄=200 sccm

High frequency power (the upper electrode/the lower electrode): 600 W/100 W

Pressure: 2.66 Pa(20 mTorr)

Temperature (ceiling/side wall/wafer loader): 80° C./60° C./30° C.

Time: 45 seconds

(Etching of the Polysilicon Layer)

Process gas: HBr/CF₄/Ar=380/50/100 sccm

High frequency power (the upper electrode/the lower electrode): 300 W/100 W

Pressure: 2.66 Pa(20 mTorr)

Temperature (ceiling/side wall/wafer loader): 80° C./60° C./60° C.

Time: 180 seconds

(Etching (Ashing) of the Second Photoresist Pattern and the Anti-Reflection Film)

Process gas: O₂=350 sccm

High frequency power (the upper electrode/the lower electrode): 300 W/100 W

Pressure: 13.3 Pa(100 mTorr)

Temperature (ceiling/side wall/wafer loader): 80° C./60° C./60° C.

Time: 180 seconds

Next, as shown in FIG. 1I, the left silicon dioxide film 106 is removed by wet cleaning using hydrofluoric acid, SMP (sulfuric acid/peroxide), APM (ammonia/peroxide) or the like (Operation 209 in FIG. 2).

Through the above operations, an island-patterned polysilicon in which a plurality of island-like patterns is arranged with a predetermined narrow pitch can be formed. FIG. 6 is an electron micrograph showing a shape of the island-patterned polysilicon actually prepared. As can be seen from this electron micrograph, the island-shaped patterns of polysilicon can be formed by cutting through the line-shaped patterns having a line width of about 20 nm and the distance between the lines being about 20 nm, so that the distance between the island-shaped patterns is about 20 nm. Such island-shaped patterns of polysilicon may be used as, for example, a gate layer of SRAM.

As described above, according to this embodiment, it is possible to form desired fine patterns with higher precision and more efficiency than those in conventional techniques.

In addition, in the above process, before forming the silicon dioxide (SiO₂) film (insulating film) 106 at the portion including the inside of the hole of the second photoresist pattern 105 and performing the shrinking process to shrink the hole size (Operation 205 in FIG. 2), the second photoresist pattern 105 may be slimmed. Such slimming allows an intermediate exposed region of the photoresist to be selectively removed to provide a good shape of patterns, while allowing scum (residual resist) in the bottom of the hole to be removed.

In control of the hole shape of the second photoresist pattern 105, a ratio of a vertical dimension (long diameter) to a horizontal dimension (short diameter) of the elliptical hole can be controlled for the shape of the second photoresist pattern 105 with shrinked hole size as shown in FIG. 5, and accordingly, it is possible to make a shape after the shrinking process thinner and longer (smaller in the horizontal dimension) by slimming.

For example, when the silicon dioxide (SiO₂) film (insulating film) is directly formed and the shrinking process to shrink the hole size is performed for a photoresist pattern having a ratio of vertical dimension/horizontal dimension=2.14 (the vertical dimension: 137.2 nm, the horizontal dimension: 64.1 nm), a ratio of vertical dimension/horizontal dimension=3.74 was achieved. On the contrary, for the same photoresist pattern, when a slimming process is first performed, and then the silicon dioxide (SiO₂) film (insulating film) is formed and the shrinking process to shrink the hole size is performed, a ratio of vertical dimension/horizontal dimension=4.02 was achieved.

This slimming process may be either continuously performed as a wet process using an application and development apparatus after forming the second photoresist pattern 105 or as a dry process using a batch processing furnace before forming the silicon dioxide (SiO₂) film (insulating film) 106. The dry process may be performed using oxygen plasma (for example, a capacitive coupling plasma with flow rate of oxygen gas of 1000 sccm, pressure of 20 Pa (150 mTorr) and high frequency power of 50 W). In addition, for the wet process, application of a slimming agent (solvent which does not directly dissolve resist), bake [before and after 70° C. (with a slightly acidic surface of resist)] and development by TMAH (Tetra Methyl Ammonium Hydroxide) (with dissolution of acidic surface of resist) may be carried out.

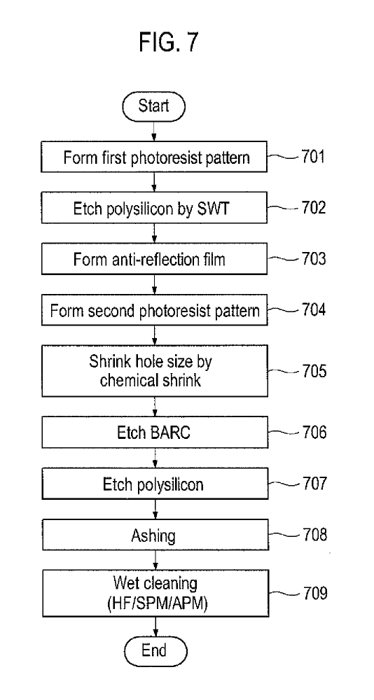

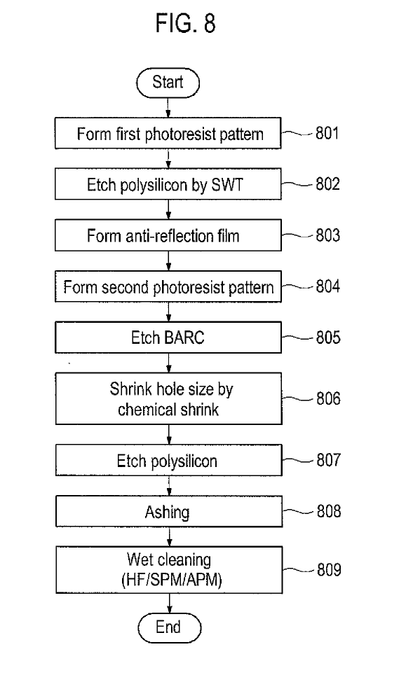

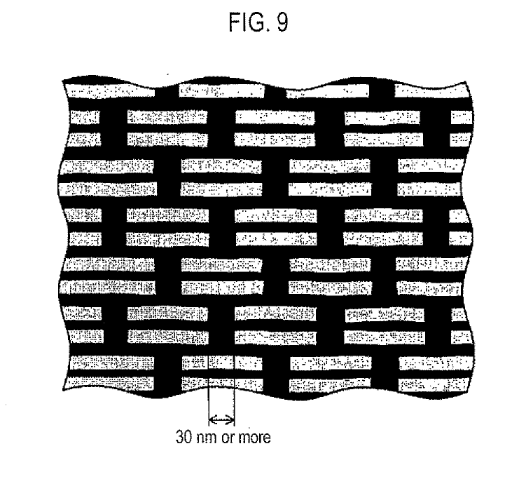

However, instead of the shrinking process for the hole size by the formation of the insulating film (silicon dioxide) in the above embodiment, if chemical shrink using chemicals is performed as shown in the flow diagrams of FIGS. 7 and 8, the fineness of the hole size is restricted and the hole shape approaches from the first elliptical shape to a circular shape. This makes it difficult to control a short diameter of the ellipse to be below 30 nm and prevents the interval between the line-shaped patterns from being below about 30 nm, as shown in FIG. 9.

In addition, the flow diagram of FIG. 7 shows a case where the chemical shrink is performed (Operation 705 in FIG. 7), the anti-reflection film is etched (Operation 706 in FIG. 7) and then the polysilicon is etched (Operation 707 in FIG. 7). In addition, the flow diagram of FIG. 8 shows a case where the anti-reflection film is etched (Operation 805 in FIG. 8) the chemical shrink is performed (Operation 806 in FIG. 8) and then the polysilicon is etched (Operation 807 in FIG. 8). Other operations are the same as those in the embodiment shown in the flow diagram of FIG. 2.

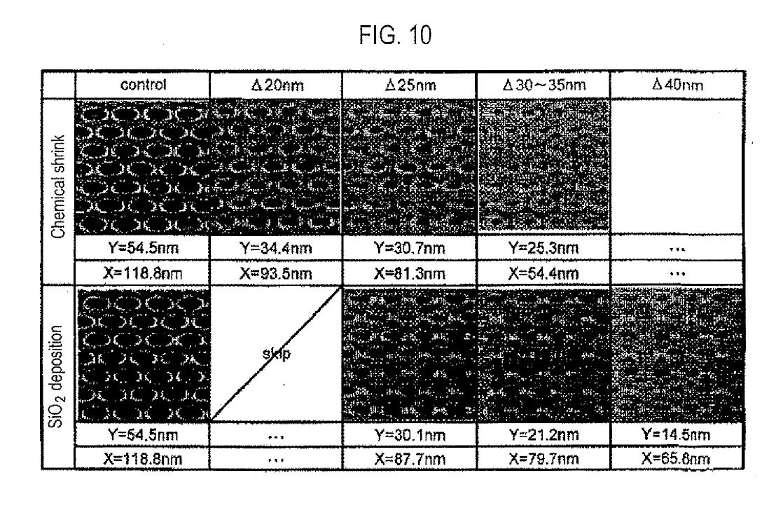

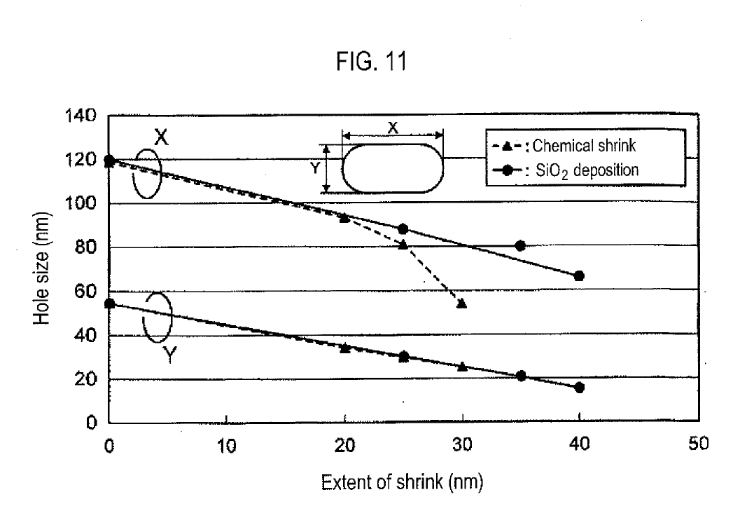

FIG. 10 shows results of an examination in the difference between shrink by MLD of the silicon dioxide (SiO₂) film in this embodiment and chemical shrink for an elliptical hole. In this figure, the upper part shows micrographs and sizes of a hole in X and Y direction for chemical shrink and the lower part shows micrographs and sizes of a hole in X and Y direction for shrink by MLD of the silicon dioxide (SiO₂) film. FIG. 11 is a graph showing a relationship between an extent of shrink and a hole size, where a vertical axis represents a hole size and a horizontal axis represents the extent of shrink.

Here, an initial hole size before shrink is Y=54.5 nm and X=118.8 nm. In addition, the chemical shrink was performed at a processing temperature of 150 to 200° C. using RELACS (trade name) as chemicals.

As shown in FIGS. 10 and 11, for the shrink by MLD of the silicon dioxide (SiO₂) film, the hole size can be shrunk while maintaining the elliptical shape; however, for the chemical shrink, the extent of shrink in the X direction increases and the hole shape approaches a circular shape without maintaining the elliptical shape.

While the exemplary embodiments of the present disclosure have been illustrated above, it is to be understood that the present disclosure is not limited to the disclosed embodiments but may be modified in various ways. For example, although it has been illustrated in the above embodiments that island-shaped patterns of polysilicon used as a gate layer of SRAM are formed, a shape of the patterns is not limited thereto.

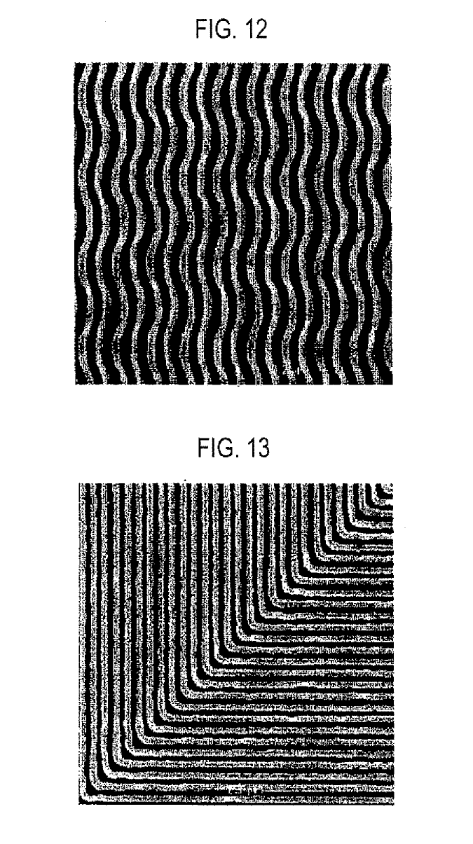

For example, although it has been illustrated in the above embodiments that the polysilicon film 101 has a linear line and space pattern, the polysilicon film 101 may have a wavy pattern as shown in an electron micrograph of FIG. 12, or may have a substantially right-angled shape as shown in an electron micrograph of FIG. 12.

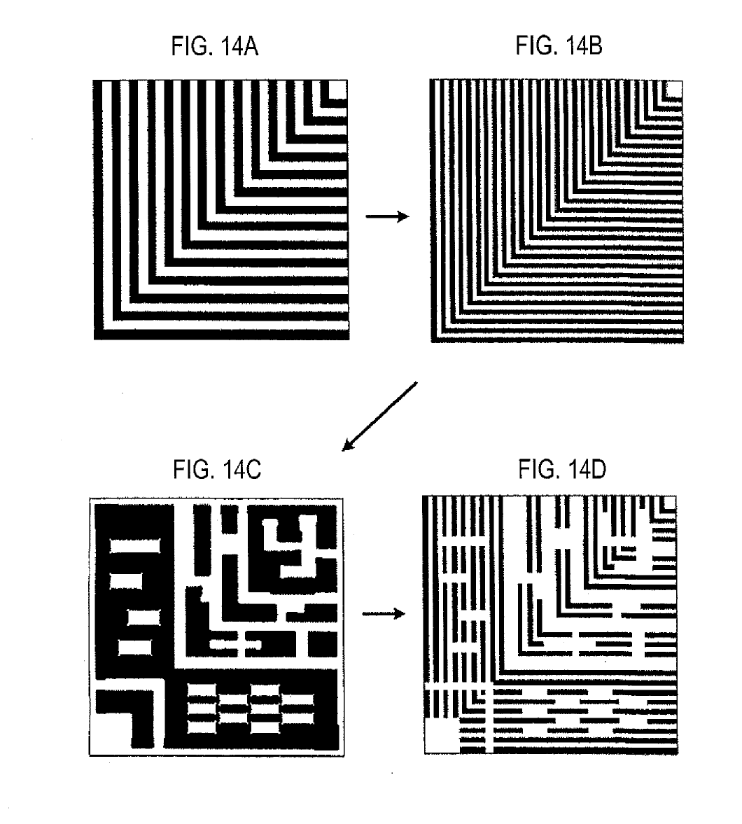

In addition, for example, this may be employed for patterning of logics as shown in FIGS. 14A to 14D. In the example shown in FIGS. 14A to 14D, a substantially right-angled photoresist pattern is first formed as shown in FIG. 14A, and polysilicon is etched after narrowing a pitch of this pattern by means of side wall transfer, as shown in FIG. 14B. Next, a mask used to cut the pattern is formed by photoresist, as shown in FIG. 14C, and the polysilicon is etched using this mask after shrink by an insulating film, as shown in FIG. 14D.

The semiconductor device manufacturing method of the above embodiment has industrial applicability as it can be applied to the field of manufacturing semiconductor devices.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A method of manufacturing a semiconductor device, the method comprising:
forming a thin film on a substrate;
forming a a photoresist layer having an elliptical hole pattern on the thin film;
shrinking a hole size of the elliptical hole pattern by forming an insulating film on a side wall of the elliptical hole pattern; and
etching the thin film using the insulating film and the photoresist layer which form the elliptical hole pattern having the shrinked hole size as a mask.

2. A method of manufacturing a semiconductor device, the method comprising:
etching a thin film formed on a substrate based on a first pattern;
depositing the first pattern formed on the thin film;
forming a photoresist layer with a second pattern on the first pattern;
shrinking a hole size of the second pattern by forming an insulating film on a side wall of the second pattern of the photoresist layer; and
etching the thin film using the insulating film and the photoresist layer which form the second pattern having the shrinked hole size as a mask.

3. The method of claim 2, wherein the insulating film comprises one selected from a group comprising silicon oxide (SiO₂), silicon nitride (SiN), aluminum oxide (Al₂O₃), aluminum nitride (AlN), titanium oxide (TiO₂) and amorphous silicon.

4. The method of claim 2, wherein the insulating film is formed at a temperature of 140° C. or below.

5. The method of claim 2, further comprising sliming the second pattern before shrinking a hole size.

6. A method of manufacturing a semiconductor device, the method comprising:
forming polysilicon having a first parallel pattern by etching a polysilicon film formed on a semiconductor wafer substrate based on a photoresist having at least some of the parallel first pattern formed on the polysilicon film;
depositing the first pattern of the polysilicon as an anti-reflection film;
forming a photoresist with a second pattern on the first pattern;
shrinking a hole size of the second pattern by forming an insulating film on the photoresist;
exposing the polysilicon film by etching the anti-reflection film and the insulating film of the bottom of the hole using the insulating film and the photoresist which form the shrinked second pattern as a mask; and
forming a polysilicon pattern by etching the polysilicon film based on a new hole obtained in the exposing.

7. The method of claim 6, wherein the insulating film comprises one selected from a group consisting of silicon oxide (SiO₂), silicon nitride (SiN), aluminum oxide (Al₂O₃), aluminum nitride (AlN), titanium oxide (TiO₂) and amorphous silicon.

8. The method of claim 6, wherein the insulating film is formed at a temperature of 140° C. or below.

9. The method of claim 6, further comprising removing the anti-reflection film and the photoresist on the polysilicon by ashing and wet cleaning.

10. The method of claim 6, further comprising sliming the second pattern before shrinking a hole size.
